(19) United States
(12) Patent Application Publication
(10) Pub. No.: US 2008/0291953 A1
(43) Pub. Date: Nov. 27, 2008

(54) Light-Emitting System Provided with an Integrated Control Photosensor and a Method for Producing Said System

(75) Inventor: Philippe Gilet, St Quentin sur Isere (FR)

Correspondence Address: OBLON, SPIVAK, MCCLELLAND MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 12/095,416

(22) PCT Filed: Dec. 4, 2006
(86) PCT No.: PCT/EP2006/069260

§ 371 Date: May 29, 2008

(30) Foreign Application Priority Data
Dec. 6, 2005 (FR) 05 53736

(51) Int. Cl. H01S 3/13; H01S 5/183

(52) U.S. Cl. 372/29.01; 372/50.124

(57) ABSTRACT

Light-emitting system comprising an integrated control photodetector and method for fabricating said system.

This system is particularly suitable for optical connections and comprises a light-emitting electronic component (2) and a light guide (4) that receives the light emitted by the component, said guide comprising a light input face (8) arranged facing the component and reflecting a part of the light it receives, and a photodetector (14) integrated with the component and that detects a part of the light emitted by said component, wherein said photodetector is placed near to the component and is capable of receiving a part of the light reflected by the light input face. The active layer of the light-emitting electronic component is made of the same material as the active layer of the photodetector.

### TECHNICAL FIELD

The present invention concerns the field of optoelectronics and more specifically the fabrication of a light emitter and means of controlling the light intensity supplied by said emitter.

More precisely, the invention concerns a light emission system comprising a light-emitting electronic component, provided with an integrated control photodetector, as well as a method for fabricating said system.

The invention applies more specifically to VCSEL type components, in other words vertical cavity surface emitting lasers, and resonant cavity light-emitting diodes.

It finds applications particularly in all systems that use optical connections and, more generally, in all systems that comprise light emitters and which require the light intensity of said emitters to be controlled, said emitters being, for example, VCSEL or RCLED.

It should be recalled that a RCLED is a structure that is virtually identical to a VCSEL but in which the mirrors have a lower reflectivity.

The invention applies, for example, to high speed optical connections, intra-chip optical connections, intra-board optical connections and optical connections in free space.

All of these connections require a perfectly stabilised light power, automatically controlled by an APC (Automatic Power Control) type system.

Moreover, the emission-reception from a CMOS (hybridization) chip is an application that is perfectly adapted to the invention (by providing, for example, an optic bus).

### STATE OF THE PRIOR ART

The level of compactness of optoelectronic components has to meet the increasing miniaturisation of emission-reception modules.

In addition, such modules are required to be more and more efficient while at the same time being less and less expensive.

Consequently, techniques that enable the integration density of components on chips to be increased are continuously being sought.

In this respect, reference should be made to the following documents:

[1] Vertical-Cavity Lasers with an Intracavity Resonant Detector, Sui F. Lim et al., IEEE Journal of selected topics in quantum electronics, vol. 3, no 2, 1997, pages 416 to 421 [2] Power Control of VCSEL Arrays Using Monolithically Integrated Focal Plane Detectors, Mohammad Azadeh et al., Journal of Lightwave Technology, vol. 20, no 8, 2002, pages 1478 to 1484

[3] International application WO 03/000019, published on the 3 Jan. 2003, Integrated photodetector for VCSEL feedback control.

In a conventional light emitting system, two separate components are generally implanted:
the emission component, for example a stripe laser or a VCSEL, and
a detection component that makes it possible to control the light power emitted, from the collection of a fraction of said light power, as happens in APC type systems.

In the case of a Fabry-Perot type laser, it is easy to use a photodiode for the collection. Indeed, since the two faces of the laser are accessible and the light is even emitted by the face opposite to the actual emission face, it is easy to arrange a photodiode facing this opposite face.

On the other hand, in the case of a VCSEL, the means associated with said VCSEL for the collection of a part of the light power are generally external: photodetection components are placed near to the VCSEL (see for example the document [3]).

Indeed, the two very high reflectivity mirrors of the VCSEL are not necessarily accessible and the lateral leakage of light is extremely low.

Nevertheless, it has already been proposed fabricating a monolithic structure comprising a VCSEL and an additional resonant cavity for the detection, this cavity being integrated with the stacking of layers of the VCSEL. It should however be noted that the integration of such a cavity increases the production time (due to the additional epitaxy steps) and lowers the manufacturing output.

### DESCRIPTION OF THE INVENTION

The aim of the present invention is to overcome the previous drawbacks.

It proposes integrating the control photodetector, preferably a photodiode, as close as possible to the chip of the VCSEL or the RCLED, more generally the light-emitting electronic component, and exploiting the external part, or peripheral part, of the light beam emitted by this component. Particularly in the case of a VCSEL, this part is the least useful of the beam.

However, in numerous cases, the light emitted by the VCSEL is injected into a light guide, generally an optic fibre.

In the present invention, it is thereby proposed to measure the light injected into this optic fibre to control this light. And, to do this, it is proposed using the light that is reflected at the surface of the fibre and which is therefore redirected towards the VCSEL.

In a precise manner, the subject of the present invention is a light emission system comprising:
a light-emitting electronic component,
a light guide that is provided to receive the light emitted by the component, said light guide comprising a light input face that is arranged facing the component and that reflects a part of the light that it receives, and
a photodetector that is integrated with the component and provided to detect a part of the light emitted by said component, wherein said photodetector is placed near to the component and capable of receiving a part of the light that is reflected by the light input face,

in which the active layer of the light-emitting electronic component is made of the same material as the active layer of the photodetector.

By the expression “photodetector that is integrated with the component”, it should be understood that, according to an essential characteristic of the system that is the subject of the invention, the active layer (light emitting layer) of the light emitter component and the active layer (light detecting layer) of the photodetector are made of the same material. This has nevertheless been made clear above.

The advantage that results from this essential characteristic is threefold: the integration on the system is facilitated, the fabrication of this system is facilitated and the detection of light is facilitated since this detection occurs at the same wavelength as the emission.

Preferably, the photodetector is an annular photodiode that surrounds the component.

According to one specific embodiment of the invention, the component is a vertical cavity surface emitting laser, said laser comprising first and second mirrors that delimit the cavity, the first mirror lying on a substrate and the second mirror being placed facing the light input face.

Preferably, the system that is the subject of the invention further comprises a support to which is fixed the light guide and said support is fixed to the assembly formed by the component and the photodetector in such a way that the light input face is placed facing the component.

The present invention also concerns a method of fabricating the light emission system that is the subject of the invention, in which
the component and the photodetector are formed on a substrate, the component having first and second faces, lying on the substrate by its first face and emitting the light by its second face, and
the light guide is arranged in such a way that the light input face is facing the second face of the component.

According to one specific embodiment of the method that is the subject of the invention,
the component is a vertical cavity surface emitting laser and the photodetector is a cavity photodiode, said laser and the photodiode each comprising first and second mirrors, that delimit the corresponding cavity, and an active layer placed in this cavity,
a stacking of layers is formed on the substrate, enabling the formation of the first and second mirrors, the cavity and the active layer of the laser and the photodiode, the first mirror of each of these then being in contact with the substrate, and
the laser and the photodiode are formed from the stacking.

According to a preferred embodiment of this method, the reflectivity of the second mirror of the photodiode is furthermore reduced.

Preferably, the first and second mirrors of the laser and the photodiode are Bragg mirrors and the second mirror of the photodiode is etched to reduce its reflectivity.

Preferably, the light guide is fixed to a support and said support is fixed to the substrate in such a way that the light input face is facing the second face of the component.

The support is preferably fixed to the substrate through the intermediary of solder balls, by the flip chip technique, with which the fabrication method, which is the subject of the invention, is advantageously compatible.

The present invention also has other advantages:
it makes it possible to fabricate simultaneously the light emitter component and the photodetector, instead of fabricating said photodetector independently of the component and integrating it with said component since the invention makes it possible, particularly in the case of a VCSEL, to use the active layer that generates the light provided by the VCSEL as light detection layer,
it enables arrays or matrices of electronic light emitting components, especially VCSEL, to be used while integrating if necessary intelligent control functions forming pixels, in the immediate proximity of the VCSEL-detector assemblies on a control circuit, by hybridization of said assemblies on a control circuit that is for example of CMOS type,
it enables the production costs of VCSEL in which the light emission is controlled by an APC type system to be substantially reduced, and
it enables the fabrication of matrix components having a low pitch, with an individual control of the power emitted by each VCSEL.

### BRIEF DESCRIPTION OF DRAWINGS

The present invention will be better understood on reading the description of embodiments provided hereafter, given solely by way of indication and in no way limiting, and by referring to the appended figures, in which:

FIG. 1 is a schematic sectional view of one example of the light emission system that is the subject of the invention, and

FIGS. 2 to 5 schematically illustrate the steps of a method for fabricating said device.

### DETAILED DESCRIPTION OF SPECIFIC EMBODIMENTS

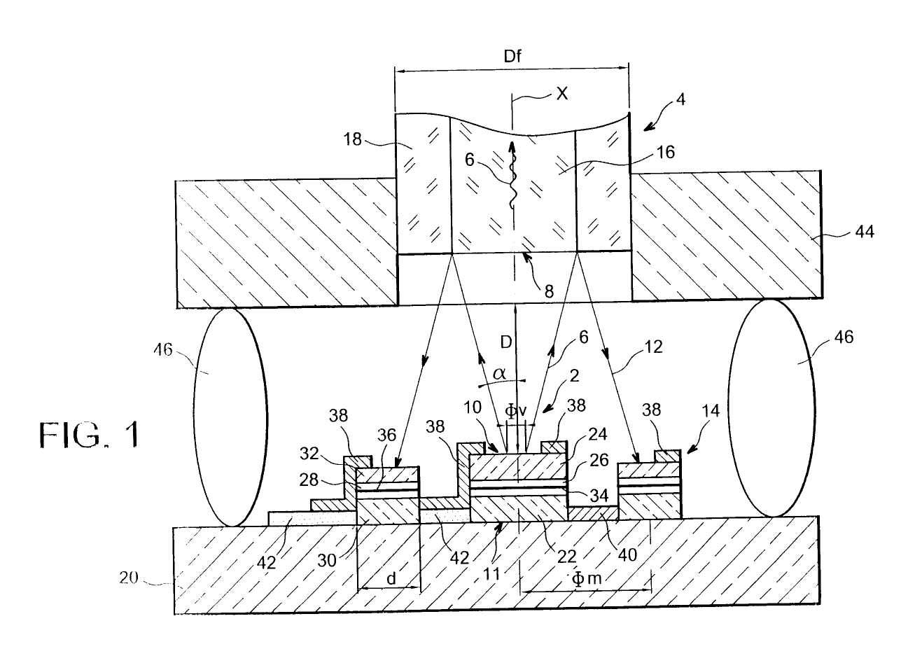

FIG. 1 is a schematic sectional view of one example of the light emission system that is the subject of the invention.

The system of FIG. 1 comprises a light-emitting electronic component 2 and a light guide 4 that is provided to receive the light 6 emitted by the component. Said light guide comprises a light input face 8 that is arranged facing the component or, more precisely, the face 10 of said component (front face), by which the light 6 is emitted (the other face of the component, or rear face, having the reference 11 in FIG. 1). The input face 8 reflects a part 12 of the light that it receives from the component.

The system also comprises a control photodetector 14 that is integrated with the component 2 and provided to detect a part of the light emitted by said component. Said photodetector 14 is placed near to the component 2 and is capable of receiving a part of the light 12 that is reflected by the light entry face 8.

In the example, the component is a VCSEL, the light guide 4 is an optic fibre and the photodetector 14 is a cavity photodiode; moreover, this photodiode 14 surrounds the VCSEL 2 and the example formed by this VCSEL and the photodiode has a symmetry of revolution around an X axis.

Said X axis also constitutes the axis of the optic fibre 4 of which the core 16 and the optical cladding 18 can be seen.

The VCSEL and the annular cavity photodiode are formed on a substrate 20 that is for example in GaAs. On this substrate 20, the VCSEL 2 and the photodiode 14 are formed by epitaxy, from a same stacking of appropriate layers.

The lower mirror 22 of the VCSEL, which lies on the substrate 20, the upper mirror 24 of the VCSEL, which is arranged facing the light entry face 8, and the cavity 26 of the VCSEL, which is delimited by the mirrors 22 and 24, may be seen.

Similarly, the cavity 28 of the photodiode, delimited by a lower mirror 30, in contact with the substrate 20, and by an upper mirror 32 which is on the side of the light entry face 8 may be seen.

The VCSEL comprises an active layer 34 that is situated in the cavity 26 and serves to generate the light 6. In the cavity 28 of the photodiode, there is also an active layer 36 that correspond to the layer 34, and which is made of the same material as this latter layer, but which serves as detection layer, to detect the part of the light 12 that the photodiode receives.

The mirrors 22 and 30 are N-doped whereas the mirrors 24 and 32 are P-doped. Electrodes 38 that are in contact with the P-doped mirrors 24 and 32 and an electrode 40 that is in contact with the N-doped mirrors 22 and 30 may be seen. The layers 42, which can be seen in FIG. 1, are passivation layers.

Thanks to the electrodes 38 and 40, the VCSEL may be controlled by an injection current and the current generated by the photodiode when it receives a part of the light 12 may be collected.

The injection current of the VCSEL may be enslaved to the current that is generated by the photodiode. The excitation current of the VCSEL and thereby the power of the light beam 6 generated by this VCSEL can therefore be regulated. The electronic means enabling the regulation of this power comprise the photodiode 14. The remainder of these means is not represented.

As is seen in FIG. 1, the end of the optic fibre 4, which receives the light emitted by the VCSEL, is fixed to a support 44 that is itself fixed to the substrate 20 in such a way that the axis of the optic fibre, to which the light entry face 8 is perpendicular, coincides with the X axis.

In the example, the support 44 is a wafer, for example in silicon, which comprises a punch through. The end of the optic fibre is inserted and fixed in this punch through, for example by means of adhesive. Moreover, the wafer 44 is fixed to the substrate 20 by a flip chip type hybridization by means of solder balls 46 that are for example in indium. In a purely indicative and no way limiting manner, said balls have a diameter of 30 μm.

The light beam 12 to be detected, which stems from the reflection of the light beam 6 on the face 8 of the optic fibre, firstly crosses the upper mirror 32 of the photodiode.

However, the fabrication of the VCSEL requires mirrors of very high reflectivity, greater than 99%, with a very narrow cavity peak. The mirrors 30 and 32, of the same nature as the mirrors 22 and 24 of the VCSEL, therefore also have this high reflectivity.

Without any specific precautions, the quantity of light that would arrive at the level of the detection layer 36 would be limited by this high reflectivity. To increase this quantity, it is therefore preferable to increase the spectral width of the peak of the cavity of the photodiode (Fabry-Perot cavity).

To do this, the reflectivity of the mirror for the input of the light to be detected (mirror 32) is reduced. This reduction is possible, in the present case, by a dry or wet etching operation carried out during a step of fabrication of the system.

It should be noted that this operation is possible since the light 12 arrives via the upper face of the photodiode, a face that is accessible.

However, the mirrors 22, 24, 30 and 32 are, in a known manner, Bragg mirrors in which layers of different optical indices alternate.

An etching of the upper Bragg mirror of the photodiode (mirror 32), enabling half of the alternations to be eliminated, enables a strong increase in the quantity of light transmitted by the mirror 32 thereby modified.

By way purely as an indication and in no way limiting
the diameter Φv of the zone of the face 10 of the VCSEL, though which the light beam 10 exits, is 30 μm,
the distance Df between this face 10 and the light receiving face 8 is 100 μm,
the half-angle α at the summit of the light beam 10 (substantially conical beam) is 10°,
the exterior diameter of the optical cladding 18 of the fibre is 125 μm,
the difference d between the exterior and interior radii of the photodiode, is 15 μm, and
the average diameter Φm of the photodiode (half-sum of the interior and exterior diameters of said photodiode) is 70 μm.

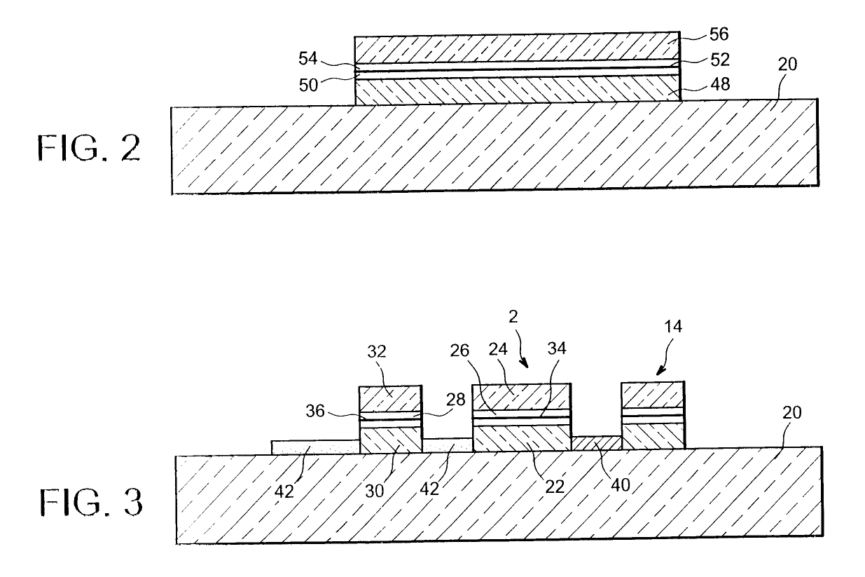

A method for fabricating the system of FIG. 1 is described hereafter in reference to FIGS. 2 to 5.

On the substrate 20 (FIG. 2), are successively formed:
a first stacking 48 of layers (alternations of N-doped semiconductor layers of different optical indices), from which the mirrors 22 and 30 will be formed,
a layer 50 from which the lower part of the cavities 26 and 28 will be formed,
a layer 52 from which the active layers 34 and 36 will be formed,
a layer 54 from which the remainder of the cavities 26 and 28 will be formed, and
a second stacking 56 of layers (alternations of P-doped semiconductor layers of different optical indices), from which the mirrors 24 and 32 will be formed.

A standard process is begun enabling the VCSEL 2 and the photodiode 14 to be fabricated (FIG. 3): the necessary mesas are etched from the previously formed stacking, and the electrode 40 and the passivation layers 42 are formed.

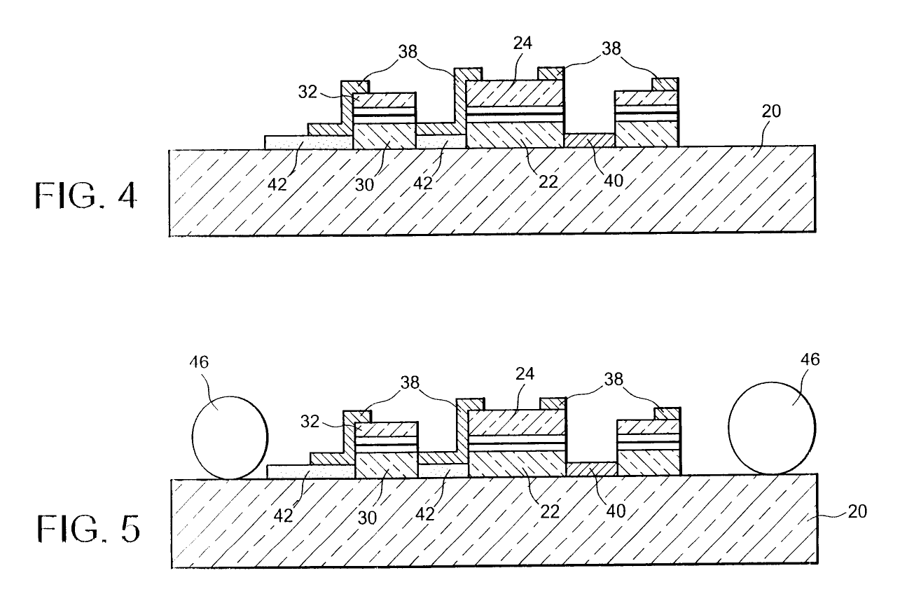

This standard process is ended (FIG. 4) the reflectivity of the mirror 32 that has been formed previously is reduced by mesa etching. To reduce said reflectivity, half of this mirror 32 is removed so that its thickness is reduced by half. Then the electrodes 38 are formed. Then, the electrodes 38 and 40 are annealed.

The balls 46 (FIG. 5) are then put in place, then the wafer 42 is hybridized, punched through from end to end, by the flip chip technique, by means of said balls.

After this hybridization, the end of the optic fibre is inserted into the wafer 42 then the fibre is immobilised in the position where its axis coincides with the X axis.

1-10. (canceled)

11: A light emission system comprising:
a light-emitting electronic component;
a light guide configured to receive the light emitted by the component, the light guide comprising a light input face arranged facing the component and that reflects a part of the light that it receives; and
a photodetector integrated with the component and provided to detect a part of the light emitted by the component, wherein the photodetector is placed near to the component and is configured to receive a part of the light that is reflected by the light input face;
wherein the active layer of the light-emitting electronic component is made from a same material as the active layer of the photodetector.

12: A system according to claim 11, wherein the photodetector is an annular photodiode that surrounds the component.

13: A system according to claim 11, wherein the component is a vertical cavity surface emitting laser, the laser comprising first and second mirrors that delimit the cavity, the first mirror lying on a substrate and the second mirror faces the light input face.

14: A system according to claim 11, further comprising a support to which is fixed the light guide, the support fixed to the assembly formed by the component and the photodetector such that the light input face faces the component.

15: A method for fabricating the light emission system according to claim 11, wherein
the component and the photodetector are formed on a substrate, the component having first and second faces, lying on the substrate by its first face and emitting the light by its second face; and
the light guide is configured such that the light input face faces the second face of the component.

16: A method according to claim 15, wherein
the component is a vertical cavity surface emitting laser, and the photodetector is a cavity photodiode, the laser and the photodiode each comprising first and second mirrors, that delimit the corresponding cavity, and an active layer placed in the cavity;
a stacking of layers is formed on the substrate, enabling formation of the first and second mirrors, the cavity and the active layer of the laser and the photodiode, the first mirror of each of these then being in contact with the substrate; and
the laser and the photodiode are formed from the stacking.

17: A method according to claim 16, wherein the reflectivity of the second mirror of the photodiode is moreover reduced.

18: A method according to claim 17, wherein the first and second mirrors of the laser and the photodiode are Bragg mirrors and the second mirror of the photodiode is etched to reduce its reflectivity.

19: A method according to claim 15, wherein the light guide is fixed to a support and the support is fixed to the substrate such that the light input face faces the second face of the component.

20: A method according to claim 19, wherein the support is fixed to the substrate through an intermediary of solder balls by a flip chip technique.
